(19) United States
(12) Patent Application Publication
(10) Pub. No.: US 2018/0374705 A1
(43) Pub. Date: Dec. 27, 2018

(54) INTEGRATED TRANSIENT VOLTAGE SUPPRESSOR CIRCUIT

(71) Applicant: QUALCOMM Incorporated, San Diego, CA (US)

(72) Inventors: Vijayakumar Dhanasekaran, San Diego, CA (US); Ramkumar Sivakumar, San Diego, CA (US); Arash Mehrabi, San Diego, CA (US)

(21) Appl. No.: 15/632,040

(22) Filed: Jun. 23, 2017

(51) Int. Cl. H01L 21/265; H01L 27/08; H01L 29/93; H01L 29/861; H01L 27/02; H01L 29/87; H01L 29/06

(52) U.S. Cl. CPC H01L 21/265; H01L 27/0814; H01L 29/93; H01L 29/0649; H01L 27/0255; H01L 29/87; H01L 29/861

(57) ABSTRACT

A transient signal protection circuit includes an input node coupled to a signal line configured to carry an output signal from a first circuit to a second circuit, wherein the signal line is subject to experiencing an unwanted reverse signal from the second circuit to the first circuit. The transient signal protection circuit also includes a comparator module configured to output a clamping signal when it is determined that the unwanted reverse signal includes a value that falls outside an acceptable range of the first circuit; and a power switch coupled to the comparator module and configured to couple the input node to a sink node when the comparator module outputs the clamping signal.

### BACKGROUND

### Field

Aspects of the present disclosure relate generally to electrical power protection circuits, and more particularly, to an integrated transient voltage suppressor circuit.

### Background

Despite a move to protect mobile devices such as smart phones from environmental hazards including water and dust, almost all mobile devices still have to contend with charging and other interface issues. For example, certain smart phone housing designs provide waterproofing and dustproofing, but many still require ports for charging, data, and/or audio. These ports need to be protected from electrical surges that may be caused by electrostatic discharge (ESD).

Mobile devices such as smart phones often include an audio port for connecting headphones or headsets. These audio ports, referred to as audio jacks, may suffer damage when a large electrical surge is encountered. For example, audio jack damage may occur when the smart phone is connected to an improperly grounded desktop speaker.

High voltage surges affect device robustness in various use/abuse conditions: a) some part or all of a chipset for the device may be damaged; b) the device may shutdown; or c) temporary functional fail may occur.

A low-cost, simple solution to protecting devices from damage caused by ESD or high voltage surges would be desirable.

### SUMMARY

The following presents a simplified summary of one or more aspects of the disclosure for implementing an integrated transient voltage suppressor circuit in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides a transient signal protection circuit that includes an input node coupled to a signal line configured to carry an output signal output from a first circuit to a second circuit, wherein the signal line is subject to experiencing an unwanted reverse signal from the second circuit to the first circuit; a comparator module configured to output a clamping signal when it is determined that the unwanted reverse signal comprises a value that falls outside an acceptable range of the first circuit; and a power switch coupled to the comparator module and configured to couple the input node to a sink node when the comparator module outputs the clamping signal.

Another aspect of the disclosure provides a transient signal protection circuit that includes an input node coupled to a signal line configured to carry an output signal output from a first circuit to a second circuit, wherein the signal line is subject to experiencing an unwanted reverse signal from the second circuit to the first circuit; comparator means for outputting a clamping signal when it is determined that the unwanted reverse signal comprises a value that falls outside an acceptable range of the first circuit; and a power switch coupled to the comparator means and configured to couple the input node to a sink node when the comparator means outputs the clamping signal.

Yet another aspect of the disclosure provides a method for protecting against a transient signal. The method includes detecting, on an input node coupled to a signal line configured to carry an output signal output from a first circuit to a second circuit, an unwanted reverse signal from the second circuit to the first circuit; generating a clamping signal when it is detected that the unwanted reverse signal comprises a value that falls outside an acceptable range of the first circuit; and coupling the input node to a sink node based on receipt of the clamping signal.

These and other aspects of the disclosure will become more fully understood upon a review of the detailed description, which follows.

### BRIEF DESCRIPTION OF THE DRAWINGS

These and other sample aspects of the disclosure will be described in the detailed description that follow, and in the accompanying drawings.

FIG. 1 is a circuit diagram of a prior art transient voltage suppressor circuit.

FIG. 2 is a circuit diagram of the prior art transient voltage suppressor circuit of FIG. 1 shown coupled to a power source.

FIG. 3 is a circuit diagram of another prior art transient voltage suppressor circuit.

FIG. 4 is a conceptual diagram of an integrated transient voltage suppressor circuit configured in accordance with various aspects of the disclosure.

FIG. 5 is a circuit diagram of an active clamp circuit configured in accordance with various aspects of the disclosure that may be used in the integrated transient voltage suppressor circuit of FIG. 4.

FIG. 6 is a circuit diagram providing further details for an active clamp circuit configured in accordance with various aspects of the disclosure that may be used in the integrated transient voltage suppressor circuit of FIG. 4.

FIG. 7 is a plot of various signals in an audio codec chip/headphone circuit during an example operation of the integrated transient voltage suppressor circuit of FIG. 4 for a surge event.

FIG. 8 is a flow diagram of an operation of the integrated transient voltage suppressor circuit of FIG. 4 in accordance with various aspects of the disclosure.

In accordance with common practice, some of the drawings may be simplified for clarity. Thus, the drawings may not depict all of the components of a given apparatus (e.g., device) or method. Finally, like reference numerals may be used to denote like features throughout the specification and figures.

### DETAILED DESCRIPTION

The detailed description set forth below in connection with the appended drawings is intended as a description of various configurations of an integrated transient voltage suppressor circuit but is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

The IEC61000-4-5 standard as promulgated by the International Electrotechnical Commission (IEC) provides a standard for lightning and industrial protection where a protected device must be able to withstand, during an event referred to as a surge event, a high surge current and up to 80V, generally referred to as a surge signal. To comply with the standard, certain criteria must be met when the protected device is subject to the surge signal. Three of the criteria are that the protected device shall not be damaged after the surge event; the protected device shall not reset during the zap event; and the protected device shall continue to play audio after the zap event.

Existing solutions for suppressing transient voltages typically utilize transient-voltage-suppression (TVS) diodes, which are electronic components used to protect electronic devices from voltage spikes induced on wires connected to the electronic devices. TVS diodes operate by shunting excess current when the induced voltage exceeds the avalanche breakdown potential. An example of an electronic device that can be protected by the TVS diode is an integrated circuit, commonly referred to as a chip. Because these TVS diodes are placed externally to the chip being protected these existing solutions are sensitive to board layout and RF filter placement, which renders them ineffective while still being far more complex and expensive to implement.

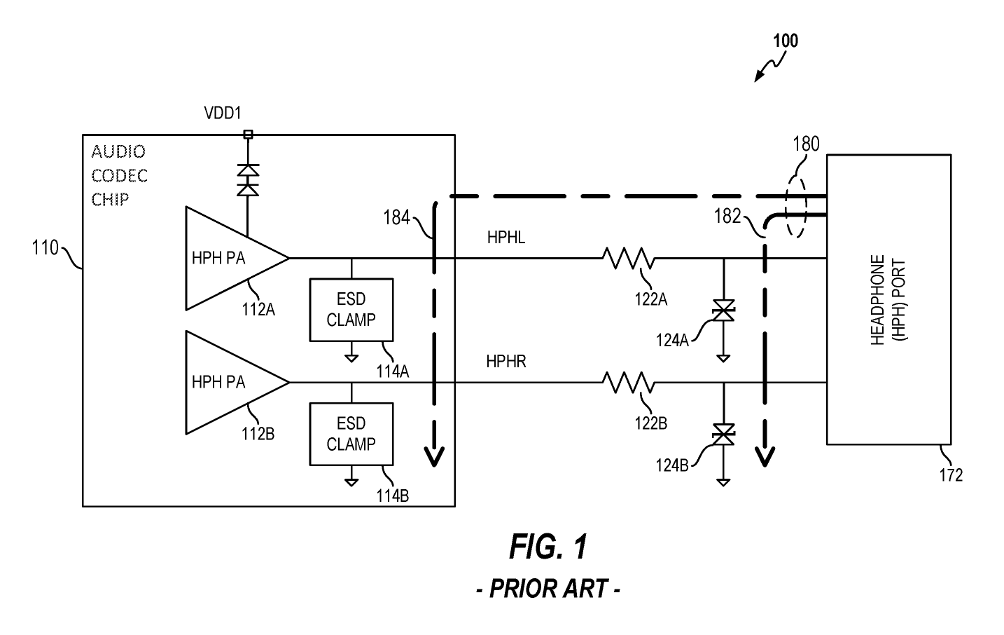

FIG. 1 illustrates a scenario 100 where, in accordance with a prior art approach, a transient signal protection configuration 102 is used to provide transient signal protection for an audio codec chip 110 in a device such as a smart phone. The audio codec chip 110 includes ports for both a left headphone (HPH) channel (HPHL) and a right HPH channel (HPHR), each powered by a power amplifier (HPH PA) 112A, 112B. Each HPH PA 112A, 112B will also have an ESD clamp device 114A, 114B that is implemented on the audio codec chip 110.

The HPHL and HPHR channels of the audio codec chip 110 are connected to external audio devices using an HPH port 172 in the transient signal protection configuration 102. The HPH port 172 can experience surge signals, referred to as zap currents, from various sources in certain instances. For example, the HPH port 172 can experience surge signals when an improperly grounded audio device such as a desktop speaker or stereo receiver. Even with the ESD clamp devices 114A, 114B, a large enough surge signal will permanently damage the HPH PA 112A, 112B of the audio codec chip 110 and other electronic components of the device. At best, as further explained here, the device may be adversely affected temporarily, such as caused to be reset. Preferably, to limit or avoid the negative effects of the surge signal, the zap current of the surge signal needs to be shunted to ground before it reaches the audio codec chip 110.

In the prior art, a pair of TVS diodes 124A, 124B, one for each of the HPHL and HPHR channels, are used in transient signal protection configuration 102 to shunt surge signals to ground before it reaches the audio codec chip 110. For example, the TVS diodes 124A, 124B are low capacitance bidirectional ESD protection diodes. Although the TVS diodes 124A, 124B can shunt some of the surge signal, a portion of it will still remain. In addition, to limit current entering the audio codec chip 110, the resistor 122A, 122B is used in each path of the audio codec chip 110. In the example, a resistor may be placed in-line with each of the HPHL and HPHR channels.

Continuing to refer to FIG. 1, a surge signal 180 is illustrated as a zap current made up of two portions—namely, zap currents 182, 184. The zap current 182 is the portion of the zap current that is shunted through the TVS diodes 124A, 124B. The zap current 184 is the portion of the zap current that then continues to audio codec chip 110 through the resistors 122A, 122B. However, the rest of the current from the surge signal 180, specifically zap current 184, must be addressed by the ESD clamp devices 114A, 114B in an attempt to protect the audio codec chip 110.

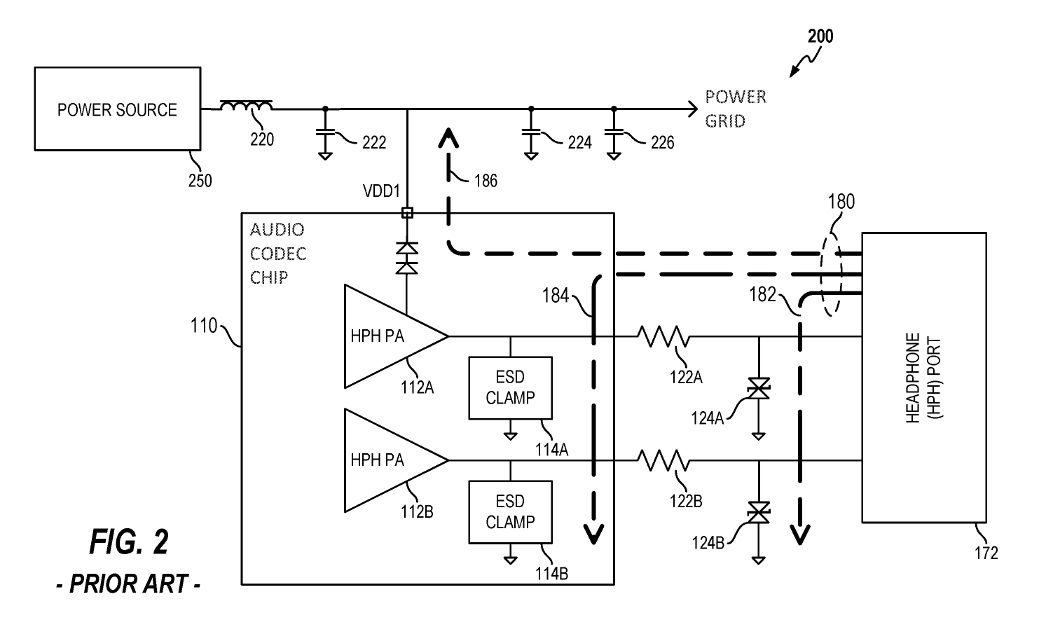

The mobile device in which the audio codec chip 110 is located typically includes several other circuits and chips, all powered by a single power supply providing a voltage labeled as “VDD1”. FIG. 2 illustrates a scenario 200 of what occurs where a power source 250 is used to provide power to the audio codec chip 110 and other integrated circuits (not shown) in a power grid in the mobile device when a surge signal with a positive voltage, such as the 80V surge signal noted above, is experienced. An inductor 220 and a capacitor 222 may be used as part of the power source 250. A pair of capacitors 224, 226 are also used to further reduce fluctuations in the power signal provided to the other integrated circuits in the power grid.

In the scenario 200, the surge signal is still represented as the surge signal 180 from the scenario 100 of FIG. 1 with zap currents 182, 184, and an additional zap current 186 being the current that reaches the power source 250. As discussed above, the TVS diodes 124A, 124B will only be able to shunt approximately a portion of the surge signal 180 to ground, illustrated as the zap current 182, which leaves a residual current, illustrated as the zap current 184, to the audio codec chip 110. The ESD clamp devices 114A, 114B in the audio codec chip 110 will attempt to clamp the zap current 184. However, because the ESD clamp devices 114A, 114B have a holding voltage, an unacceptably high voltage will develop at the HPH output ports of the audio codec device 110 during the zap event. Consequently, a reverse current, illustrated as the zap current 186, will be generated in the power grid because VDD1 is lower than the voltage at the HPH output ports. The zap current 186 will charge the capacitors 224, 226 and increase the voltage level experienced by the power grid. For example, although the power signal provided for a power grid typically has a voltage level that is under 2V, the zap current 186 will significantly increase the voltage level.

The increase of the voltage level experienced by the power grid due to the reverse current of the zap current 186 will cause a system error condition because of an overvoltage condition. The system error condition will then result in a reset of the mobile device. An issue also exists for the prior art approach of the transient signal protection configuration 102 when the surge signal has a negative voltage. In this case, there will be an over-current drawn from the power grid that will cause a system error condition due to an under-voltage condition, also resulting in a reset of the mobile device.

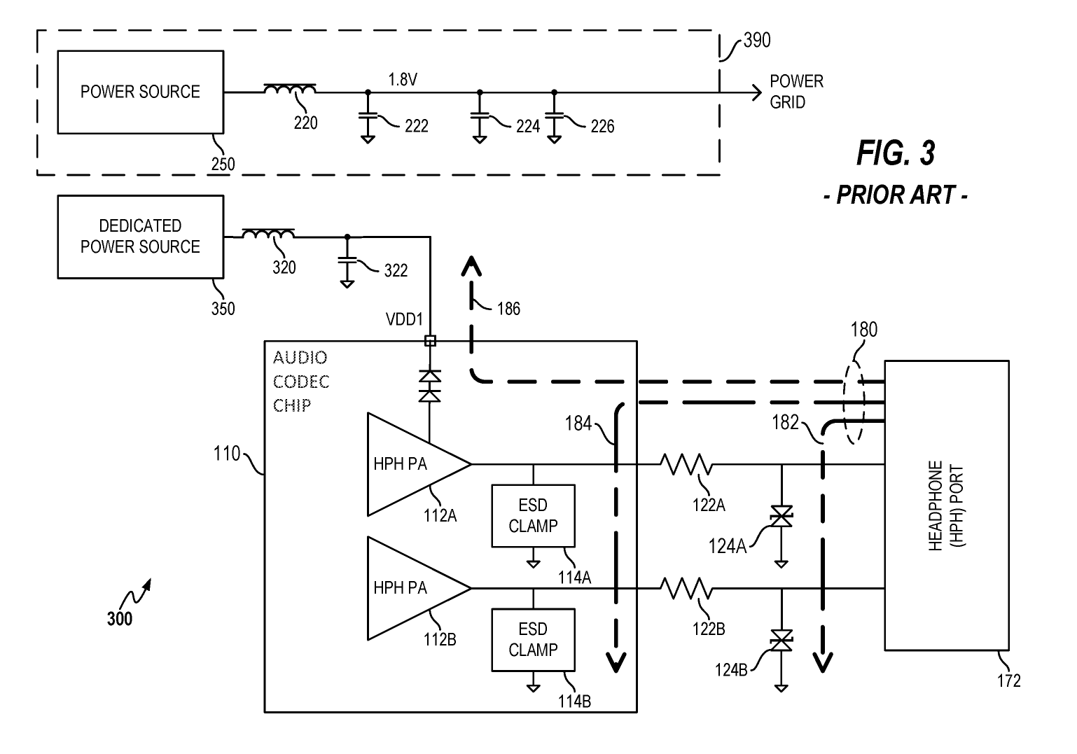

Another prior art approach that attempts to address the deficiencies of the prior art approach of the transient signal protection configuration 102 includes multiple power supplies. FIG. 3 illustrates a scenario 300 where a dedicated power source such as a second power source 350, an example of which is a DC/DC converter, is used to provide power to the audio codec chip 110. The second power source 350 is used to isolate the power system of the audio codec chip 110 from the power source 250 and other integrated circuits in the device, and thus prevent voltage fluctuations in the main system power grid from a zap event experienced by the transient signal protection configuration 102. As such, the system error condition from the zap event that causes a reset of the device will be prevented because the power system for the audio codec chip 110 is made independent of any other power system of the device.

Although the prior art approach of FIG. 3 minimizes the possibility of system errors and resets due to zap events, the addition of a separate power system adds complexity and cost to the device. This is extremely undesirable where the device is a mobile device. Further, this approach does not address any functional failure that will arise from zap events, such as a reset to the audio codec chip due to the zap event or audio mute.

Various aspects of the disclosure provide transient signal protection for an integrated circuit in a chip using on-chip circuits to implement an active clamp circuit. The active clamp circuit that may be provided by the integrated transient voltage suppressor circuit described herein may emulate passive TVS diode functionality. The active clamp circuit may achieve an extremely low trigger voltage and provide dynamic resistance. Where the integrated circuit to be protected is in a chip such as the audio codec chip, the active clamp circuit may operate to clamp audio amplifier output in the presence of large electrical surge signals in order to prevent system failure.

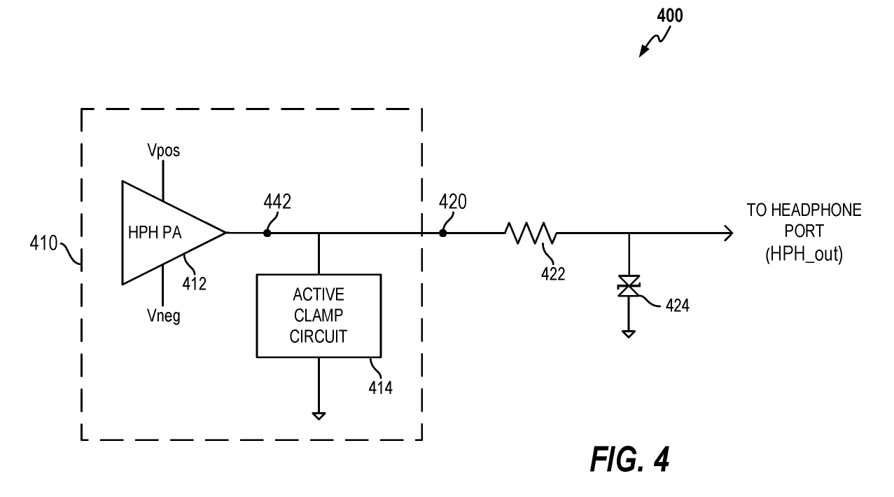

FIG. 4 illustrates a transient signal protection configuration 400 that includes an active clamp circuit 414 for providing protection for an audio codec chip 410 that may include a pair of HPH PA channels, one for each channel in a stereo configuration. However, only one HPH PA, an HPH PA 412, is shown to avoid complicating the discussion. The HPH PA 412 is coupled to an audio codec chip output node 420 of the audio codec chip 410. Support circuitry outside of the audio codec chip 410 that is inline between an HPH port and the audio codec chip 410 includes a resistor 422 and a TVS diode 424.

In one aspect of the disclosure, the active clamp circuit 414 may be placed between an HPH PA output node 442 of the HPH PA 412 and the audio codec chip output node 420 of the audio codec chip 410 to act as a clamp at the audio codec chip output node 420. The active clamp circuit 414 may be used to replace prior art ESD clamp devices. In one aspect of the disclosure, the active clamp circuit 414 may emulate the operation of TVS diodes and serves to shunt any zap current at the audio codec chip output node 420. For example, the active clamp circuit 414 may offer the same protection provided by a conventional passive TVS diode from such damage because of electrical overstress (EOS) or other thermal damage that may occur when an electronic device is subjected to a current or voltage that is beyond specified limits of the device. However, as further described herein, the active clamp circuit 414 may also ensure no functional failures such as a device reset or audio mute will occur because of the active clamp circuit 414 provides a clamping threshold that is a target maximum clamping voltage at the audio codec chip output node 420 of the audio codec chip 410.

During a zap event, the active clamp circuit 414 may shunt the zap current arriving from the resistor 422 to maintain the voltage level at the audio codec chip output node 420 at a very low level. The active clamp circuit 414 may also maintain a low clamping, or holding, voltage at the audio codec chip output node 420, thereby ensuring that there will be no reverse current returning to the power grid. For example, given a surge signal described in the examples previously discussed, the voltage level at the HPH PA output node 442 of the HPH PA 412 will be limited to a voltage level that will not create a reverse current back to the power grid.

In general, the active clamp circuit 414 may be triggered when the voltage level at the audio codec chip output node 420 is outside of a range of voltages referred to as a trigger voltage range. Thus, during a zap event, the active clamp circuit 414 will detect and subsequently shunt a surge signal that causes the voltage level at the audio codec chip output node 420 to be outside of the trigger voltage range. In addition, the active clamp circuit 414 may continue to operate as long as the voltage level at the audio codec chip output node 420 is outside of a range of voltages referred to as a holding voltage range. Thus, the active clamp circuit 414 will continue to shunt the surge signal as long as the voltage level at the audio codec chip output node 420 remains outside of the holding voltage range. The voltage levels that make up the end points of the trigger voltage range may be adjustable. Similarly, the voltage levels that make up the end points of the holding voltage range may also be customized. The trigger voltage range and the holding voltage range do not have to be equal. Thus, the active clamp circuit 414 may use different voltages ranges for the trigger voltage range and the holding voltage range. Further, the voltage levels for the voltage range end points may be chosen from such voltage levels as a supply rail voltage level or a customized voltage level.

In accordance with one aspect of the disclosure, the active clamp circuit 414 may include one or more hysteretic comparators, each of which compares the input of the active clamp circuit 414 (i.e., the voltage level at the audio codec chip output node 420) with a respective threshold voltage level to detect a surge signal and trigger operation of the active clamp circuit 414 to shunt the surge signal to ground. In addition, the comparators may be configured so that the holding voltage range of the active clamp circuit 414 is different than the trigger voltage range such that the holding voltage range is within the trigger voltage range. For example, the positive voltage level end point for the trigger voltage range, such as that used to handle a surge signal with a positive voltage, is sufficiently higher than the positive voltage level end point for the holding voltage range. Similarly, the negative voltage level end point for the trigger voltage range, such as that used to handle a surge signal with a negative voltage, is sufficiently lower than the negative voltage level end point for the holding voltage range. It should be noted that although the discussion provided herein may use voltage ranges with a positive voltage level end point and a negative voltage level end point, those skilled in the art would recognize the applicability of the various aspects of the disclosure to voltage ranges that are completely located in a positive voltage domain or, conversely, are completely located in a negative voltage domain.

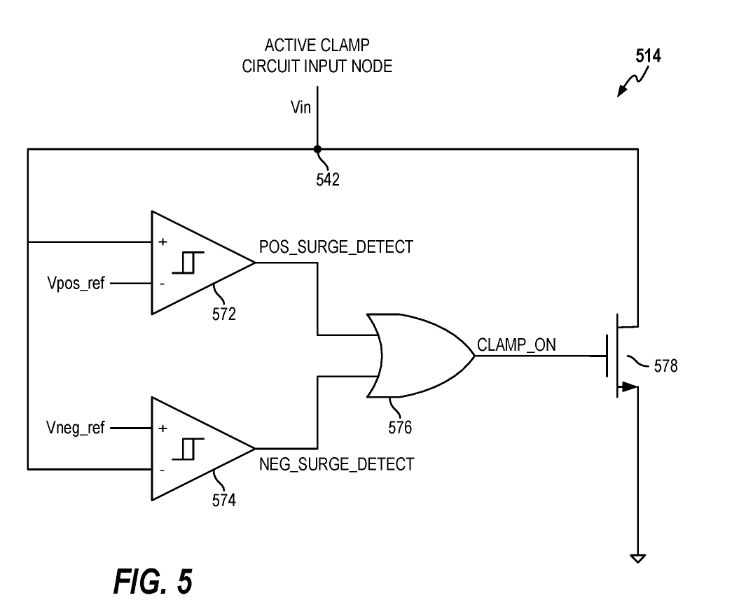

FIG. 5 illustrates an active clamp circuit 514 configured in accordance with one aspect of the disclosure that may be implemented as the active clamp circuit 414. The active clamp circuit 514 may be powered by the power source used for the rest of the circuits in the audio codec chip 410. Thus, the active clamp circuit 514 may always be available to handle surge signals. The active clamp circuit 514 includes an active clamp circuit input node 542 that may be coupled to the HPH PA output node 442 of the HPH PA 412, which is effectively the audio codec chip output node 420. An input signal (Vin) received at the active clamp circuit input node 542 is provided to both a first comparator 572 and a second comparator 574. Each of the comparators has an output that is coupled to control a power switch 578, where the output of each comparator may activate the power switch 578 to then shunt any surge current received at the active clamp circuit input node 542 to ground, as further described herein. In one aspect of the disclosure, an OR gate 576 may be used to couple the outputs of the first comparator 572 and the second comparator 574 to the power switch 578.

In addition to receiving the input signal from the active clamp circuit input node 542, each of the comparators also receives an input that provides a voltage end point from a voltage range. These voltage end points may also be referred to as threshold voltages. In one aspect of the disclosure, each of the comparators may be used to compare the input signal received at the active clamp circuit input node 542 to a threshold voltage. Using two comparators, i.e., the first comparator 572 and the second comparator 574, it may be determined when the input signal is outside of a voltage range defined by an upper limit, defined by Vpos_ref, and a lower limit, defined by Vneg_ref. Because in accordance with various aspects of the disclosure each comparator is configured to be hysteretic (i.e., each comparator may remain activated over a range of voltages), each of these limits may further include its an upper hysteresis limit and a lower hysteresis limit. For example, Vpos_ref includes a Vpos_trigger that defines a triggering voltage level for triggering clamping for a positive surge event and a Vpos_hold that defines a holding voltage level such that, until the input signal (Vin) falls below that holding voltage level, the clamping will continue. Without hysteresis, the clamping may oscillate, which is undesirable. Vneg_ref also includes upper and lower hysteresis limits referred to as Vneg_hold and Vneg_trigger, respectively, where the upper hysteresis limit refers to a voltage level that is higher (e.g., less negative) than the lower hysteresis limit. In one aspect, the relationship between these voltage levels may be seen as:

Vpos_trigger>Vpos_hold>0>Vneg_hold>Vneg_trigger, (1)

where it is assumed that Vpos_ref (having a hysteresis range of [Vpos_trigger, Vpos_hold]) is for handling positive surge events where the input signal (Vin) has a positive surge voltage level, and Vneg_ref (having a hysteresis range of [Vneg_hold, Vneg_trigger]) is for handling negative surge events where the input signal (Vin) has a negative surge voltage level.

In general, Vpos_trigger and Vneg_trigger may define the upper and lower end points of a trigger voltage range to trigger a clamping operation, while Vpos_hold and Vneg_hold define the upper and lower end points of a holding voltage range to continue the clamping operation after the clamping operation has been triggered. These ranges control the operation of the comparators, as further detailed herein. For example, before the clamping operation has been triggered, the first comparator 572 may operate with an input with a Vpos_trigger voltage level as a first threshold voltage, and the second comparator 574 may receive an input with a Vneg_trigger voltage level as a second threshold voltage, where the Vpos_trigger and Vneg_trigger voltage levels are the upper and lower limits of the trigger voltage range, respectively. After the clamping operation has been triggered, such as by a positive surge event, the first comparator 572 may operate with an input having a Vpos_hold voltage level with which to compare the voltage level of the input signal (Vin) such that the clamping operation continues to operate if the voltage level of the input signal (Vin) remains above the Vpos_hold voltage level. In a similar fashion, after the clamping operation has been triggered, such as by a negative surge event, the second comparator 574 may operate with an input having a Vneg_hold voltage level with which to compare the voltage level of the input signal (Vin) such that the clamping operation continues to operate if the voltage level of the input signal (Vin) remains below the Vneg_hold voltage level.

In accordance with various aspects of the disclosure, the voltage ranges for the trigger and the holding voltage ranges may be chosen separately. In one aspect of the disclosure, the voltage range may be chosen based on an operational voltage range for the HPH PA 412. For example, the trigger voltage range may be chosen based on what the HPH PA 412 may tolerate so that a surge event will not damage the device. In another aspect of the disclosure, the voltage range may be based on a desired voltage range to minimize any impact of a surge event, such as a holding voltage range that would minimize system reset errors due to excessive reverse current to the power grid. In other various aspects of the disclosure, the voltage range may be based on other parameters, including a parameter such as the voltage levels of a power rail that is used in the device.

Continuing to refer to FIG. 5, during a triggering phase of the active clamp circuit 514 when the input signal either exceeds the voltage range or falls below the voltage range defined by Vpos_trigger and Vneg_trigger, the power switch 578 may be controlled to couple the active clamp circuit input node 542 to a sink such as ground. For example, the first comparator 572 and the second comparator 574 may be used to determine if a voltage level of the input signal detected at the input of the active clamp circuit 514 (i.e., the voltage level at the active clamp circuit input node 542) is outside of the trigger voltage range, where the voltage level of the input signal is outside of the trigger voltage range when the voltage level of the input signal is detected to be either greater than Vpos_trigger by the first comparator 572, or lower than Vneg_trigger by the second comparator 574. The first comparator 572 will output a signal (POS_SURGE_DETECT) if the voltage level of the input signal is detected to be greater than Vpos_trigger. The second comparator 574 will output a signal (NEG_SURGE_DETECT) if the voltage level of the input signal is detected to be lower than Vneg_trigger. Either signal will cause the power switch 578 to shunt the input signal to ground when the power switch 578 receives an output (CLAMP_ON) of the OR gate 576, activating the power switch 578.

In one aspect of the disclosure, the power switch 578 may be implemented as a clamp transistor, where the gate/base of the transistor is driven by one of the first comparator 572 and the second comparator 574, the drain/collector of the transistor is connected to the active clamp circuit input node 542, and the source/emitter of the transistor is connected to ground. For example, the power switch 578 may be implemented as a power transistor such as a field effect transistor (FET), or a bipolar junction transistor (BJT). The power switch 578 will allow current to flow from the active clamp circuit input node 542 to ground. Other devices may be used to implement the power switch.

As discussed, the first comparator 572 and the second comparator 574 may be implemented using hysteretic comparators, each of which compares an input of the active clamp circuit 414 with the supply rail(s) or any threshold voltage(s). In one aspect of the disclosure, the trigger voltages that make up the voltage end points of the range may be adjustable. In another aspect of the disclosure, the holding voltages that make up end points of the range for deactivating the operation of the active clamp circuit 414 may also be customized. The hysteretic nature of the first comparator 572 and the second comparator 574 may allow a holding voltage that is different than the trigger voltage. For example, once the voltage at the active clamp circuit input node 542 drops below a holding voltage (e.g., 50 mV), the active clamp circuit 514 will disable itself.

A low holding voltage provides significant benefits and avoids issues such as the reverse current being generated to the power grid, as discussed above. Various aspects of the disclosure provide a holding voltage that is much lower than achievable by passive clamps. For example, TVS diodes cannot be used as secondary diodes at a codec output node to clamp the voltage to a level low enough to prevent a reverse current being generated to power grid. In other words, clamping voltages provided by TVS diodes are too high.

Still continuing to refer to FIG. 5, after the triggering phase of the active clamp circuit 514 when the input signal either exceeded the voltage range or fell below the voltage range defined by Vpos_trigger and Vneg_trigger, the power switch 578 may be controlled to continue to couple the active clamp circuit input node 542 to the sink until the input signal (Vin) at the active clamp circuit input node 542 either: 1) falls below the Vpos_hold voltage level for a positive surge event; or 2) rises above the Vneg_hold voltage level for a negative surge event. For example, for positive surge events, the first comparator 572 will continue to output the signal (POS_SURGE_DETECT) while the voltage level of the input signal continues to be detected to be greater than Vpos_hold. For negative surge events, the second comparator 574 will continue to output the signal (NEG_SURGE_DETECT) if the voltage level of the input signal continues to be detected to be lower than Vneg_hold. Either signal will cause the power switch 578 to continue to shunt the input signal to ground because the power switch 578 will continue to receive the output signal (CLAMP_ON) from the OR gate 576, continuing to activate the power switch 578.

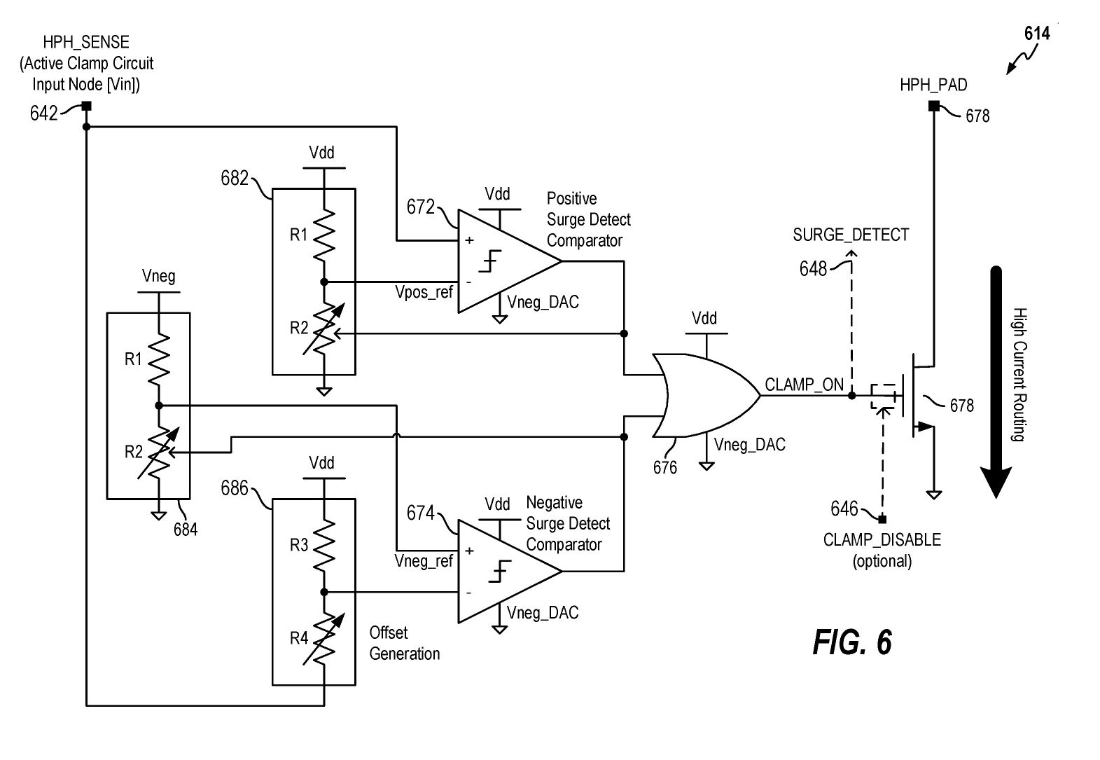

FIG. 6 illustrates an active clamp circuit 614 configured in accordance with another aspect of the disclosure that may be implemented as the active clamp circuit 414. Similar to the active clamp circuit 514, the active clamp circuit 614 may be powered by the power source used for the rest of the circuits in the audio codec chip 410. Thus, the active clamp circuit 614 may always be available to handle surge signals. The active clamp circuit 614 includes an HPH_SENSE node 642, which is an active clamp circuit input node, that may be coupled to the HPH PA output node 442 of the HPH PA 412 (labeled as “HPH_SENSE”), which is effectively the audio codec chip output node 420. An input signal (Vin) received at the active clamp circuit input node 642 is provided to both a first comparator 672 and a second comparator 674. Each of the comparators has an output that is coupled to control a power switch 678, where the output of each comparator may activate the power switch 678 to then shunt any surge current at an HPH_PAD node 644 to ground, as further described herein. In some aspects, the HPH_PAD node 644 may be the considered to be same node as the HPH_SENSE node 642. In other aspects, the HPH_PAD node 644 may be a different node as the HPH_SENSE node 642 for flexibility in implementation.

In one aspect of the disclosure, an OR gate 676 may be used to couple the outputs of the first comparator 672 and the second comparator 674 to the power switch 678, where an output signal (CLAMP_ON) may be used to activate the power switch 678. In another aspect of the disclosure, a signal provided at a CLAMP_DISABLE node 646 may be used to control whether clamping provided by the active clamp circuit 614 is active by controlling whether the output signal (CLAMP_ON) is allowed to activate the power switch 678. A SURGE_DETECT node 648 may be used to provide an indicator to an outside circuit that a surge event has been detected, which may be independent to whether the signal is provide at the CLAMP_DISABLE node 646. Thus, in yet another aspect of the disclosure, the active clamp circuit 614 may be used as a surge event detector.

The first comparator 672 and the second comparator 674 may be comparators that independently detect positive and negative surge events, respectively. Similar to how the first comparator 572 and the second comparator 574 operate, the first comparator 672 or the second comparator 674 may be triggered when an output signal at the HPH PA output node 442 of the HPH PA 412 outputs exceed a set reference range for triggering clamping. Either the first comparator 672 and the second comparator 674 may then activate a shunt to clamp that output signal, as discussed above.

In accordance with various aspects of the disclosure, a pair of reference generation modules with a first reference generation module 682 and a second reference generation module 684 that may be used to set a trigger point for each comparator, respectively, in response to a surge event. Specifically, the reference generation module 682 may set the trigger point for the first comparator 672 and the reference generation module 684 may set the trigger point for the second comparator 674. In one aspect of the disclosure, each reference generate module includes a first resistor R1 and a second resistor R2 that define a resistor ladder that may be used to set the trigger point. Feedback from an output of each comparator may be provided to the associated resistor ladder to create hysteretic behavior once clamping is triggered to avoid oscillations and ensure reliable clamping until the surge event dies down. For example, the first reference generation module 682 receives the output of the first comparator 672 at the second resistor R2 to create a feedback loop, which affects a Vpos_ref input for the first comparator 672 that is coupled to a junction between the first resistor R1 and the second resistor R2 of the first reference generation module 682. As another example, the second reference generation module 684 receives the output of the second comparator 674 at the second resistor R2 to create a feedback loop, which affects a Vneg_ref input for the second comparator 674 that is coupled to a junction between the first resistor R1 and the second resistor R2 of the second reference generation module 684. It should be noted that the first resistor R1 and the second resistor R2 of the first reference generation module 682 may have different operating characteristics from the first resistor R1 and the second resistor R2 of the second reference generation module 684.

In some aspects of the disclosure, an offset generation module 686 may be used to avoid false interrupts when a voltage signal from a power supply is not available to the active clamp circuit 614. In one aspect of the disclosure, a small offset, which is higher than the input offset/noise of each comparator, may be added by the offset generation module 686 at the input to ensure the output of each comparator stays LOW even when all power supplies are collapsed. The offset generation module 686 may include a resistor ladder with a first resistor R3 and a second resistor R4 with a junction defined between that is coupled to a negative input of the second comparator 674.

Various means may be used to provide the transient voltage suppression approach described herein. In accordance with one aspect of the disclosure, a transient signal protection circuit may include an input node coupled to a signal line configured to carry an output signal output from a first circuit to a second circuit, wherein the signal line is subject to experiencing an unwanted reverse signal from the second circuit to the first circuit. The transient signal protection circuit may include comparator means for outputting a clamping signal when it is determined that the unwanted reverse signal includes a value that falls outside an acceptable range of the first circuit, and a power switch coupled to the comparator means and configured to couple the input node to a sink node when the comparator means outputs the clamping signal. In general, the aforementioned means may be any module, or one or more modules, described herein that is, or are, configured to perform the functions recited by any of the aforementioned means. For example, the comparator means may be implemented by the first comparator 572 and/or the second comparator 574. As another example, the comparator means may be implemented by the first comparator 672 and/or the second comparator 674.

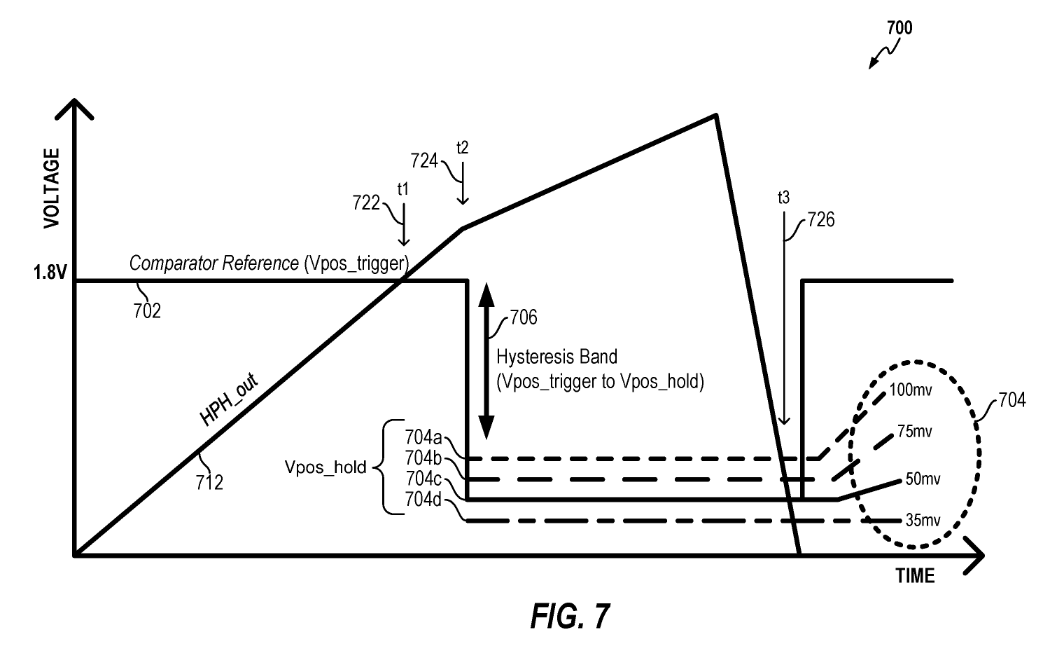

FIG. 7 illustrates an example operation of various aspects of the integrated transient voltage suppressor circuit disclosed herein, such as clamping of a positive surge event by the active clamp circuit 414 of FIG. 4, where operation of a comparator detecting positive surge events is shown in a plot 700 having voltage along an x-axis and time along a y-axis. Reference will be made to the active clamp circuit 514 of FIG. 5, although it should be noted that the description would apply equally to the active clamp circuit 614 of FIG. 6. In addition, although the following description uses the first comparator 572 in describing a clamping operation for a positive surge event, it is noted that the operation of the second comparator 574 for clamping of a negative surge event would be described in a similar manner and those skilled in the art would be able to apply the description provided here to other surge events, such as the negative surge event. In the plot 700, a comparator reference 702 is shown against an HPH_out 712. At a time t1 722, the HPH_out 712 exceeds a triggering voltage level (Vpos_trigger) of the first comparator 572, which begins to attempt to clamp the surge event at a time t2 724. At a time t3 726, when the HPH_out 712 has dropped below a holding voltage level (Vpos_hold) because of the clamping, the first comparator 572 will disable the clamping process.

The holding voltage level (Vpos_hold) may be thought of as a lower hysteresis threshold. In one aspect of the disclosure, this lower hysteresis threshold may be programmable at various levels, as illustrated by a set of programmable lower hysteresis levels 704 having voltage levels at a 100 mv level 704a, a 75 mv level 704b, a 50 mv level 704c, and a 35 mv level 704d. Thus, a hysteresis band 706 may be defined by a difference between a triggering level of the comparator reference 702 (Vpos_trigger) and a programmable hysteresis level from the hysteresis levels 704 (Vpos_hold). Feedback from the first comparator 572 is used to create hysteresis once the clamp is triggered until the surge dies down.

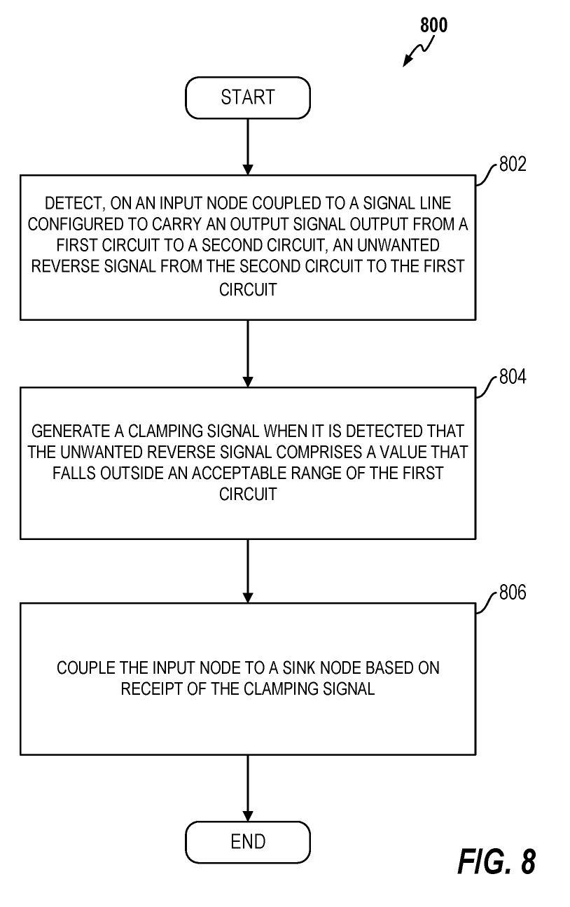

FIG. 8 illustrates a transient voltage suppression process 800 involving an operation of active claim circuit such as the active clamp circuit 414 of FIG. 4.

At 802, the active clamp circuit 414 detects, on an input node coupled to a signal line configured to carry an output signal output from a first circuit to a second circuit, an unwanted reverse signal from the second circuit to the first circuit.

At 804, the active clamp circuit 414 generates a clamping signal when it is detected that the unwanted reverse signal includes a value that falls outside an acceptable range of the first circuit. In one aspect of the disclosed approach, the acceptable range has a first threshold and a second threshold and the generation of the clamping signal includes providing a first signal when the value of the unwanted reverse signal passes the first threshold; and providing a second signal when the value of the unwanted reverse signal passes the second threshold. In effect, the active clamp circuit 414 will couple the input node to the sink node when at least one of the first signal or the second signal is received

At 806, the active clamp circuit 414 couples the input node to a sink node based on receipt of the clamping signal. In one aspect of the disclosed approach, the active clamp circuit 414 will stop the generation of the clamping signal when it is detected that the value of the unwanted reverse signal is within a second range, where the second range is within the acceptable range of the first circuit.

Several aspects of an integrated transient voltage suppressor circuit have been presented with reference to an audio codec chip. As those skilled in the art will readily appreciate, various aspects described throughout this disclosure may be extended to other devices that may utilize transient voltage suppression.

The various illustrative logical blocks, modules, and circuits described in connection with the aspects disclosed herein may be implemented within an integrated circuit (“IC”). The IC may comprise a general purpose processor, a digital signal processor (DSP), an application specific integrated circuit (ASIC), a field programmable gate array (FPGA) or other programmable logic device, discrete gate or transistor logic, discrete hardware components, electrical components, optical components, mechanical components, or any combination thereof designed to perform the functions described herein, and may execute codes or instructions that reside within the IC, outside of the IC, or both. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

It is understood that any specific order or hierarchy of steps in any disclosed process is an example of a sample approach. Based upon design preferences, it is understood that the specific order or hierarchy of steps in the processes may be rearranged while remaining within the scope of the present disclosure. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

What is claimed is:

1. A transient signal protection circuit comprising:
an input node coupled to a signal line configured to carry an output signal output from a first circuit to a second circuit, wherein the signal line is subject to experiencing an unwanted reverse signal from the second circuit to the first circuit;
a comparator module configured to output a clamping signal when it is determined that the unwanted reverse signal comprises a value that falls outside an acceptable range of the first circuit; and
a power switch coupled to the comparator module and configured to couple the input node to a sink node when the comparator module outputs the clamping signal.

2. The transient signal protection circuit of claim 1, wherein the acceptable range comprises a first threshold and a second threshold, and the comparator module comprises:
a first comparator coupled to the input node and configured to provide a first signal when the value of the unwanted reverse signal passes the first threshold; and
a second comparator coupled to the input node and configured to provide a second signal when the value of the unwanted reverse signal passes the second threshold.

3. The transient signal protection circuit of claim 2, wherein the power switch is coupled to the first comparator and the second comparator, wherein the power switch is configured to couple the input node to the sink node when at least one of the first signal or the second signal is received.

4. The transient signal protection circuit of claim 1, wherein the power switch comprises a semiconductor device comprising a gate coupled to the comparator module to receive the clamping signal from the comparator module, a drain coupled to the input node, and a source coupled to the sink node.

5. The transient signal protection circuit of claim 1, wherein the comparator module is further configured to not output the clamping signal when it is determined that the value of the unwanted reverse signal is within a second range.

6. The transient signal protection circuit of claim 5, wherein the acceptable range comprises the second range.

7. The transient signal protection circuit of claim 1, wherein the value of the unwanted reverse signal is clamped below a clamping threshold when the comparator module outputs the clamping signal.

8. The transient signal protection circuit of claim 1, wherein the first circuit comprises audio circuitry having an audio port and the transient signal protection circuit resides on a silicon substrate comprising the first circuit, and wherein the input node is coupled to the audio port.

9. A transient signal protection circuit comprising:
an input node coupled to a signal line configured to carry an output signal output from a first circuit to a second circuit, wherein the signal line is subject to experiencing an unwanted reverse signal from the second circuit to the first circuit;
comparator means for outputting a clamping signal when it is determined that the unwanted reverse signal comprises a value that falls outside an acceptable range of the first circuit; and
a power switch coupled to the comparator means and configured to couple the input node to a sink node when the comparator means outputs the clamping signal.

10. The transient signal protection circuit of claim 9, wherein the acceptable range comprises a first threshold and a second threshold, and the comparator means comprises:
a first comparator means, coupled to the input node, for providing a first signal when the value of the unwanted reverse signal passes the first threshold; and
a second comparator means, coupled to the input node, for providing a second signal when the value of the unwanted reverse signal passes the second threshold.

11. The transient signal protection circuit of claim 10, wherein the power switch is coupled to the first comparator means and the second comparator means, wherein the power switch is configured to couple the input node to the sink node when at least one of the first signal or the second signal is received.

12. The transient signal protection circuit of claim 9, wherein the power switch comprises a semiconductor device comprising a gate coupled to the comparator means to receive the clamping signal from the comparator means, a drain coupled to the input node, and a source coupled to the sink node.

13. The transient signal protection circuit of claim 9, wherein the comparator means comprises means for preventing output of the clamping signal when it is determined that the value of the unwanted reverse signal is within a second range.

14. The transient signal protection circuit of claim 13, wherein the acceptable range comprises the second range.

15. The transient signal protection circuit of claim 9, wherein the value of the unwanted reverse signal is clamped below a clamping threshold when the comparator means outputs the clamping signal.

16. The transient signal protection circuit of claim 9, wherein the first circuit comprises audio circuitry having an audio port and the transient signal protection circuit resides on a silicon substrate comprising the first circuit, and wherein the input node is coupled to the audio port.

17. A method for protecting against a transient signal, the method comprising:
detecting, on an input node coupled to a signal line configured to carry an output signal output from a first circuit to a second circuit, an unwanted reverse signal from the second circuit to the first circuit;
generating a clamping signal when it is detected that the unwanted reverse signal comprises a value that falls outside an acceptable range of the first circuit; and
coupling the input node to a sink node based on receipt of the clamping signal.

18. The method of claim 17, wherein the acceptable range comprises a first threshold and a second threshold, wherein the generation of the clamping signal comprises:
providing a first signal when the value of the unwanted reverse signal passes the first threshold; and
providing a second signal when the value of the unwanted reverse signal passes the second threshold.

19. The method of claim 18, further comprising:
coupling the input node to the sink node when at least one of the first signal or the second signal is received.

20. The method of claim 17, further comprising stopping the generation of the clamping signal when it is detected that the value of the unwanted reverse signal is within a second range.

21. The method of claim 20, wherein the acceptable range comprises the second range.
